(19) United States
(12) Patent Application Publication
(10) Pub. No.: US 2018/0326525 A1
(43) Pub. Date: Nov. 15, 2018

(54) DED ARC THREE-DIMENSIONAL ALLOY METAL POWDER PRINTING METHOD AND APPARATUS USING ARC AND ALLOY METAL POWDER CORED WIRE

(71) Applicant: BEES, INC., Daejeon (KR)

(72) Inventors: Hee-Sung ANN, Daejeon (KR); Youn-Won PARK, Daejeon (KR); Ji-Han LIM, Busan (KR)

(21) Appl. No.: 15/771,340

(22) PCT Filed: Oct. 20, 2016
(86) PCT No.: PCT/KR2016/011792

§ 371 Date: Apr. 26, 2018

(30) Foreign Application Priority Data
Oct. 26, 2015 (KR) 10-2015-0148527

(51) Int. Cl. B23K 9/04; B23K 26/34; B23K 10/02; B23K 9/10; B23K 9/12; B23K 9/16; C23C 16/513; B41F 19/00

(52) U.S. Cl. CPC B23K 9/044; B23K 26/34; B23K 10/027; B41F 19/005; B23K 9/125; B23K 9/16; C23C 16/513; B23K 9/1006

(57) ABSTRACT

A DED arc 3D alloy metal powder cored printing method, according to an embodiment of the present invention, comprises the steps of: (a) connecting a 3D printing part to a first electrode via a ground line, contacting a second electrode, in which an electrode contact tip is tapped on a peripheral surface of an alloy metal powder cored wire, and then generating an arc by a potential difference between the first electrode and the second electrode to melt the tip of the alloy metal powder cored wire and the surface of the printing part at the same time; (b) forming a monolayer by mixing and solidifying the melt of the alloy metal powder cored wire and the melt of the surface of the printing part; and (c) stacking the monolayer by continuously performing a monolayer overlay, layer-upon-layer.

### CROSS REFERENCE TO RELATED APPLICATION

This present application is a national stage filing under 35 U.S.C § 371 of PCT application number PCT/KR2016/011792 filed on Oct. 20, 2016 which is based upon and claims the benefit of priority to Korean Patent Application No. 10-2015-0148527 filed on Oct. 26, 2015 in the Korean Intellectual Property Office. The disclosures of the above-listed applications are hereby incorporated by reference herein in their entirety.

### TECHNICAL FIELD

The present invention relates to a directed energy deposition (DED) arc three-dimensional alloy metal powder printing method and an apparatus therefor, and more particularly, to a DED arc three-dimensional (3D) alloy metal powder printing method and an apparatus therefor using an arc and an alloy metal powder cored wire.

### BACKGROUND ART

Directed energy deposition (DED) 3D printing generates digital design data through computer modeling of a 3D shape, differentiates the digital design data into a two-dimensional (2D) plane, and then prints a differentiated material on a plane with a 3D printing device. The DED 3D printing is a technique for manufacturing a three-dimensional product by continuously stacking a printed object in a layer-by-layer manner. In contrast to subtractive manufacturing which produces a product by cutting or trimming a material, an official term of the DED 3D printing is called additive manufacturing (AM) or rapid prototyping (RP), and the DED 3D printing started using a polymer material at an initial stage, and now, a 3D printing using a metal material is remarkably developing. American Society for Testing and Materials (ASTM) and International Organization for Standardization (ISO) classify a 3D printing technique into seven categories as follows:

First, photo polymerization (PP): light is irradiated to polymer liquid to cause a photo polymerization curing reaction of a polymer material and to solidify the polymer liquid such that an object is manufactured.

Second, material jetting (MJ): a solution type material is sprayed and is cured using ultraviolet rays or the like such that an object is manufactured.

Third, binder jetting (BJ): a liquid phase adhesive is discharged onto a powder material and is bonded to the powder material such that an object is manufactured.

Fourth, material extrusion (ME): a material heated at a high temperature is continuously pushed out through a nozzle and is positionally moved such that an object is manufactured.

Fifth, sheet lamination (SL): thin film-shaped materials are bonded and stacked using heat or an adhesive such that an object is manufactured.

Sixth, powder bed fusion (PBF): a high energy beam (a laser or an electron beam) is injected onto a metal powder material to melt. The powders are solidified, and solidified powder is layer-by-layer stacked such that an object is manufactured.

Seventh, directed energy deposition (DED): a high energy beam (a laser or an electron beam) and metal powder are injected together, and the powders are melted by the energy and solidified layer-by-layer. Among the above-described 3D printing techniques, a technique of utilizing a metal material mostly for a three-dimensional printing is the PBF and DED techniques using a laser beam as a heat source.

In the PBF technique, a metal powder is flatly sprayed on a bed and a laser beam is selectively moved to irradiate the metal powder according to a preprogrammed path. The metal powder is locally melted and solidified to produce a two-dimensional metal layer. The bed is descended again, and then the metal powder is coated again on top of the solidified material of the 2D metal layer such that a 3D shape is manufactured by repeating the melting and solidification processes.

Meanwhile, the DED technique manufactures a 2D initial metal layer by simultaneously injecting a laser beam and a metal powder around the laser beam to melt and solidify the metal powder. Thereafter, the initial metal layer is melted by the continuous injecting laser beam, and at the same time, a metal powder injected in real time is also melted to continuously overlay single layers on the initial metal layer. Since the above processes are repeatedly performed to stack and form a 3D shape, all the process parameters are controlled in real time. Specifically, in terms of technology, the DED technique is the same as laser beam multi-pass metal powder welding or laser beam metal powder cladding.

FIG. 1A is a diagram illustrating a PBF 3D printing applied to a 3D printing of a metal material among 3D printing techniques, FIG. 1B is a diagram illustrating a DED laser beam 3D printing, and FIG. 1C is a conceptual diagram illustrating high energy laser beam metal powder welding that is the same as the DED laser beam 3D printing in terms of technology.

A technique widely used in the industry for 3D printing of a metal structure is DED laser beam 3D printing. This is a laser metal forming technique capable of rapidly manufacturing a metal product directly from 3D computer-aided design (CAD) data or a 3D program model. Metal powders are continuously supplied in a process using a high-power laser beam of 1 kW or more and are melted, solidified, and joined to each other. Since a 3D shape is configured with 2D cross-sections, a 3D CAD model or a 3D program model is sliced to a predetermined thickness, and 2D cross-sections calculated from the sliced model are layer-by-layer stacked such that the 3D shape is formed. This is academically referred to as materials increscent manufacturing (MIM) and is a basic concept of all 3D printing techniques. A metal single layer corresponding to the 2D cross section is melted and solidified by heat of a high-power laser beam. When a high-power laser beam is locally irradiated onto a metal surface, a molten pool is instantaneously formed on the metal surface. When a metal powder is supplied into the molten pool simultaneously with the formation of the molten pool, the metal powder undergoes a complete melting and rapidly solidified. At this point, the laser beam is freely moved along a path calculated from the 3D CAD model or the 3D program model and forms a metal monolayer corresponding to the 2D cross section. It is important to accurately manufacture a height of the metal monolayer corresponding to the 2D cross-section in the 3D printing. Process parameters affecting the height of the metal monolayer may be controlled in real time, and each monolayer may be manufactured identical to a metal product of the 3D CAD model.

FIG. 1A is a diagram illustrating a flow of general PBF 3D printing, FIG. 1B is a diagram illustrating a flow of DED laser beam 3D alloy metal powder printing, and FIG. 1C is a diagram illustrating a high energy laser beam alloy metal powder welding. The DED laser beam 3D alloy metal powder printing is technically identical to laser beam powder welding. Laser beam powder welding is welding which involves a melting phenomenon using high density energy converted from focused laser white light. An advantage of laser beam powder welding is that a laser is focused, and thus sophisticated parts may be joined to each other, and high speed and robot automation are possible, such that laser beam powder welding is incorporated into the DED laser beam 3D alloy metal powder printing technique.

TABLE 1

| Welding method | Heat Density (W/cm²) | Temperature (° C.) |
|---|---|---|
| Gas Welding | 10²~10³ | 2,500~3,500 |
| Arc Welding | 10⁴~10⁵ | 6,000~10,000 |
| Plasma Welding | 10⁶ | 15,000~30,000 |
| Electron Beam Welding | 10⁷~10⁸ | 20,000~30,000 |
| Laser Beam Welding | | |

Table 1 shows heat density ranges and temperature ranges according to welding methods.

As shown in Table 1, in electron beam and laser beam welding, heat density ranges 10⁷ ˜10⁸ W/cm² and temperature ranges 20,000˜30,000° C. And beam is focused in commercial devices. Referring to Table 1 and commercial devices, the existing DED laser beam 3D alloy metal powder printing technique in which a high heat is focused, and concentrated on an extremely small unit area, it may produce a key-hole type of molten pool, and significantly affect micro-structures as well as mechanical properties. Thus, focused laser or electron beam may not suitable for a heat source of 3D printing.

FIG. 2A, FIG. 2B and FIG. 2C are cross-sectional views illustrating a welded portion of gas welding, FIG. 2B arc welding, and FIG. 2C laser beam powder welding, respectively. Referring to FIG. 2, since the DED laser beam 3D alloy metal powder printing corresponds to high energy beam welding, high-speed printing is possible, but since a welded penetration depth is to be deep due to a high energy density, each of monolayers which are stacked when printing may not be a flat according to a laser output.

The DED laser beam 3D alloy metal powder printing is a process for continuously stacking welded portion of monolayers. Therefore, the printing process is the same as an overlay technique or cladding technique of general welding, and thus it is preferable that a penetration depth of the base material is shallow, and a penetration width is wide, but a surface of the welded portion may not be flat since the laser heat source is strong and focused. Further, the DED laser beam 3D alloy metal powder printing has a heat affected zone (HAZ) during printing, and printed portion and HAZ are easily hardened due to fast cooling by high temperature gradient of high energy density and high temperature.

FIG. 3A-3C are photographs of a structure of a printing part manufactured on Japanese-made mold alloy steel through DED laser beam 3D alloy metal powder printing by a Korean company. The Japanese-made alloy steel is alloy steel SKD61 (corresponding to STD61 in Korea and H13 in the United States) containing carbon (C) in the range of 0.32 to 0.42 wt % and chromium (Cr) in the range of 4.50 to 5.50 wt %. Referring to FIG. 3, it is shown that the DED laser beam 3D alloy metal powder printing part has a macrostructure (3A) and microstructure (3B) and (3C) in the form of multilayered weldments having HAZs, which is the same as general arc weldment. It is also shown that the printing parts were not flat and shallow, and a structure of the welded part is combination of hardened bainite and martensite.

TABLE 2

| | Maximum Tensile | |
|---|---|---|
| Material | Strength (MPa) | Elongation (%) |
| Wrought SKD 61 | 1,821 | 9 |
| 3D DED SKD 61 | 1,998 | 5 |

Table 2 shows comparison of measurement results of maximum tensile strength and elongation between the DED laser beam 3D alloy metal powder printed SKD 61 and wrought SKD 61. DED laser beam 3D alloy metal powder printing part showed a maximum tensile strength increase by about 10% and elongation decrease by about 40%. From these data, the laser DED is not suitable for a heat source in terms of micro-structures and mechanical properties.

As shown in Table 2, when the metal DED laser beam 3D printing is applied, a printing qualification test corresponding to a welding qualification test should be performed in advance to obtain optimized printing procedure by utilizing the optimized data. The metal DED laser beam 3D printers are required to stabilize a system for preventing external influence to inject a fine metal powder in the range of about 20˜150 μm diameter. In the metal laser beam PBF, all components of 3D printers need to be installed in a single chamber, thus a size of a bed for printing a metal product and product size are inevitably limited.

Current PBF and DED with laser or electron beam printings are always only in a flat position. Overhead, horizontal, and vertical positions can't be printed.

### Technical Solution

The objectives of the present invention are to provide optimum heat density and temperature, and further controllable heat input in DED 3D printing to get preferable micro-structures and mechanical properties in the printed parts with similar deposition rate as DED laser beam 3D printing and any positions of printing. DED arc 3D printing which are capable of controlling heat input with alloy metal powder cored wire complements followings.

First, a molten metal pool can be flat and shallow, compared to the DED laser beam 3D printing.

Second, 3D printing part develops optimum micro-structures, resulting in preferable mechanical properties. And impurity segregation and discontinuities can be controlled to get good integrity.

Third, all printing positions are possible and deposition rate is similar to the DED laser beam 3D printing.

Fourth, any sizes of products are printed without size limitation in open air condition.

Accordingly, it is an objective of the present invention to provide a DED arc 3D printing with alloy metal powder cored wire which are capable of varying micro-structures of a printed part, a physical property thereof, any printing position thereof, and a printed part penetration depth thereof. The apparatus can be either chamber type or miniaturized mobile type to easily move and handle without place limitation.

In directed energy deposition (DED) arc 3D alloy metal powder cored wire of the present invention, the method including the steps of: (a) connecting a 3D printing part to a first electrode through a ground line, bringing a second electrode on which an electrode contact tip is tapped on a circumferential surface of an alloy metal powder cored wire into contact with a portion of a surface of the printing part, and generating an arc by a potential difference between the first electrode and the second electrode to simultaneously melting a front end of the alloy metal powder cored wire and the surface of the printing part, (b) forming a monolayer by mixing and solidifying melts of the alloy metal powder cored wire and the surface of the printing part, and (c) continuously performing a monolayer overlay to stack the monolayers, layer-upon-layer and wherein the steps (a) to (c) are performed in an inert gas atmosphere, after information including a printing program, a voltage regulation, a current regulation, a wire feeding speed regulation, and a protective gas regulation is input to a direct-current (DC) constant voltage characteristic power supply device, an arc length and a wire feeding speed is automatically controlled by the printing program according to the input information. The alloy metal powder cored wire is formed by filling an alloy metal powder in a tube-shaped wire, and a heat input Q of the printing part follows the following ranges.

114 J/cm≤heat input≤136 J/cm.

Here, heat input=arc voltage (V)×arc current (A)÷printing speed of 3D printing gun (cm/sec).

A DC reverse polarity may be chosen such that negative electrons (−) are moved from the surface of the printing part to the alloy metal powder cored wire, and gas ions (+) collide with the surface of the printing part to remove oxide or impurity thin film on the surface thereof.

An arc length may be in a range of 2 to 10 mm.

According to the embodiment of the present invention to achieve the above object, the apparatus of a direct-current (DC) constant voltage characteristic power supply device includes a printing program, a voltage regulator, a current regulator, a wire feeding speed regulator, and a protective gas regulator, a wire feeding device including a wire drive motor, an alloy metal powder cored wire wound on a wire reel, and a wire feeder rotating roller configured to supply the alloy metal powder cored wire, a printing gun device including the alloy metal powder cored wire, an inert gas pipe, and a 3D printing gun enclosing the inert gas pipe located on both sides of the cored wire, a 3D printing part disposed below the printing gun device and brought in partial contact with a front end of the cored wire, and an inert gas container connected to the DC constant voltage characteristic power supply device, wherein, after information is input to the DC constant voltage characteristic power supply device, a position and a speed of a 3D printing gun is automatically controlled by a printing program according to the input information, the information includes a magnitude of a current and a wire feeding speed, the alloy metal powder cored wire is formed by filling an alloy metal powder in a tube-shaped wire to increase the melting rate of the wire and accordingly increase of printing deposition rate.

The 3D printing gun may be fixed in the 3D printing apparatus or a separate which capable of allowing the operator to perform a manual printing by holding the printing gun with a hand to repair the flawed part whatever.

### Advantageous Effects

A DED arc 3D printing method with alloy metal powder cored wire and an apparatus therefor have the following effects.

First, stable, efficient, and high-speed printing can be performed due to full automation and flexibility of selection by a program. Specifically, miniaturization and a mobile type can be achieved and thus it is not limited to a place and is possible to provide a reasonable price entry type.

Second, a heat input of a printing part can be controlled by varying voltage, current, arc length and printing speed. In arc printing, the heat input determines a shape of a molten pool, that is, a shape of the printing part. Further, since the heat input determines a cooling rate, micro-structure and mechanical properties of the printing part can be controlled.

Third, when a base material is present before printing with the 3D printing gun, chemical, physical, and mechanical properties of printing part are affected by those of the base material. An alloy metal powder cored wire is chosen with the same as those of the base material, so that a printed part can have the same and uniform chemical, physical, and mechanical properties. However, different dissimilar metal layer-by-layer printing is also possible by varying a chemical composition, a physical property, and a mechanical property at each layer. For example, stainless steel for corrosion protection may be overlaid on a carbon steel or a suitable other alloy may be overlaid on the carbon steel.

Fourth, a printing speed of a product can be controlled, and quality of the printing part can be improved. More specifically, the 3D printing gun can be rectilinearly moved over a printing line along a programmed path or can be weaved and moved in a zig-zag pattern based on the printing line to obtain a wide-width of printing part or can be in any positions. Further, since a temperature of a central portion of the printing part is higher than that of each of both ends of a width of the printing part, the printing speed may be controlled to be slow at both ends. Furthermore, both ends of the width of the printing part may be overlapped and printed to prevent deformation of the printing part due to shrinkage upon solidification.

Fifth, a printing speed can be accelerated, since the alloy metal wire as a filler metal contains alloy metal powder. When a mobile hand-held or 5 to 6 axis printing apparatus for this invention is used, printing can be performed in any position such as a flat position, an overhead position, a horizontal attitude, a vertical attitude, even an object floating in the air and the like. Since the alloy metal powder cored wire is used, an arc is stably formed with silent sound. And current flows along a cross-sectional area of the tube wire and thus a current density is high, such that melting of alloy metal powder cored wire is fast.

Sixth, monolayers having uniform thicknesses can be successively stacked at a high speed. Since an arc current flows in one direction in a direct-current (DC), the arc is stably formed, and since a monolayer having a thin thickness is overlaid and stacked by controlling an arc voltage, the monolayers can be stacked with a uniform thickness. An amount of heat transferred to a continuously supplied cored wire is large, and thus melting rates of the cored wire and the printing speed can be increased.

Seventh, inert gas is used to prevent an inflow of harmful substances from the outside, such that the quality of the printing part can be improved. And argon (Ar) as an inert gas is used, the melting rate of the cored wire can be more increased since heat is relatively more dissipated than a case in which the other inert gas is used at the same magnitude of a current, resulting in higher printing speed.

Eighth, the 3D printing apparatus of the present invention has effects in which maintenance is easier and installation is facilitated than a laser beam or electron beam DED printing apparatus. Further, since a heat input of the printing part is controllable, a printing part can be manufactured to have a desired micro-structures and mechanical properties.

Ninth, when printing is performed in the field, in a place where a printing apparatus is difficult to access to a portion due to surrounding parts, a hand-held type printing gun from the printing apparatus can be used and an operator can manually move the hand-held type printing gun to perform printing. In this case, manual printing is performed instead of automatic printing according to a program, and since the arc voltage is not varied using a constant voltage characteristic even when the arc length is varied by a manual manipulation, constant heating can be obtained such that quality of a welded part can be improved.

Tenth, there is an effect capable of preventing a defect of the printing part. A DC reverse polarity can be applied to set the cored wire as a positive (+) polarity and the base material (the printing part) to a negative (−) polarity, and thus a cleaning action can be performed to allow a positive (+) ion gas to collide with a surface of the printing part, thereby removing an oxide and or a nitride film which are present on the surface of the printing part. Further, when the arc length becomes longer, the arc voltage becomes higher and thus a penetration of the printing part becomes thinner in thickness and wider in a width, such that a flat printing part can be manufactured. That is, a desired shape of the printing part can be determined by controlling the arc length.

Eleventh, a thickness of a tube wire becomes smaller as an inner diameter of the alloy metal powder cored wire becomes larger and an outer diameter thereof becomes smaller, such that the melting rate can be increased, and accurate printing can be performed. Therefore, a printing speed and the melting rate can be varied by controlling an inner diameter, an outer diameter, and a thickness of the tube wire.

### DESCRIPTION OF DRAWINGS

FIG. 1A is a diagram illustrating a PBF 3D printing of a metal material, FIG. 1B is a diagram illustrating a directed energy deposition (DED) laser beam 3D printing, and FIG. 1C is a conceptual diagram illustrating high energy laser beam metal powder welding that is the same as the DED laser beam 3D printing in terms of technology.

FIG. 2A is a cross-sectional view illustrating a shape of a printing part by low input energy density, FIG. 2B is a cross-sectional view illustrating a shape of the printing part by medium input energy density, FIG. 2C is a cross-sectional view illustrating a shape of the printing part by high input energy density which is technically the same as the DED laser beam 3D printing.

FIG. 3A-3C are photographs of a structure of a printing part manufactured on Japanese-made mold alloy steel through the DED laser beam 3D alloy metal powder printing by a Korean company.

FIG. 4 is a block diagram of a DED arc 3D alloy metal powder printing apparatus of the present invention.

FIG. 5 is a flowchart of a DED arc 3D alloy metal powder printing method of the present invention.

FIG. 6 is an enlarged cross-sectional view of an alloy metal powder cored wire of the present invention.

FIG. 7 is an enlarged cross-sectional view of a printing gun part of the present invention.

FIG. 8 is a graph illustrating a magnitude of an arc voltage according to an arc current of the present invention.

FIG. 9 is a diagram illustrating an arc length and an arc width according to a low arc voltage and a high arc voltage of the present invention.

FIG. 10A-10C are cross-sectional views illustrating examples of electrons, an ion flow direction, a welded penetration depth, and a shape according to a polarity of the alloy metal powder cored wire.

FIG. 11 is a cross-sectional view illustrating a hand-handle printing gun of the present invention.

FIG. 12 is a cross-sectional view illustrating a mobile vehicle towed by car in which a main body of a 3D printing apparatus of the present invention loaded on a trailer and a cable and a hose separated from the main body are wound on a reel.

FIG. 13 is a cross-sectional view illustrating a helmet to protect human face and eyes from arc.

### DESCRIPTION OF REFERENCE NUMERALS

11: laser system 51: alloy metal powder cored wire
12: scanner system 52: wire reel
13: powder barrel 53: wire drive motor
14: unused powder 54: wire feeder rotating roller
15: 3D printing 60: cable and pipe assembly
16: base plate 61: wire supply motor and arc switch
17: base plate descending piston 62: printing power line
18: laser beam 63: protective gas supply line
19: alloy metal powder 64: printing program transfer circuit
20: protective gas 70: printing gun device
21: 3D printing fused material
71: 3D printing object
22: base material penetration depth
72: first electrode
23: molten pool 73: second electrode
24: base material 74: inert gas pipe
25: printing deposited material 75: printing program line
30: direct current (DC) constant voltage characteristic power supply
76: 3D printing gun
31: voltage regulator 77: helmet
32: current regulator 78: arc
33: wire feeding speed regulator 81: handle
34: protective gas regulator 82: trigger
35: DC polarity regulator 91: cable and hose holder
36: printing program 100: storage space
40: inert gas container 41: gas meter
42: regulator 43: electrical input
44: ground line 50: wire feeder

### MODES OF THE INVENTION

The advantages and features of the present invention and the manner of achieving the advantages and features will become apparent with reference to the embodiments described in detail below with the accompanying drawings. The present invention may, however, be implemented in many different forms and should not be construed as being limited to the embodiments set forth herein, and the embodiments are provided such that this disclosure will be thorough and complete and will fully convey the scope of the present invention to those skilled in the art, and the present invention is defined by only the scope of the appended claims.

Hereinafter, a directed energy deposition (DED) 3D alloy metal powder printing method using an arc and an alloy metal powder cored wire, and an apparatus therefor according to the present invention will be described in detail with reference to the drawings.

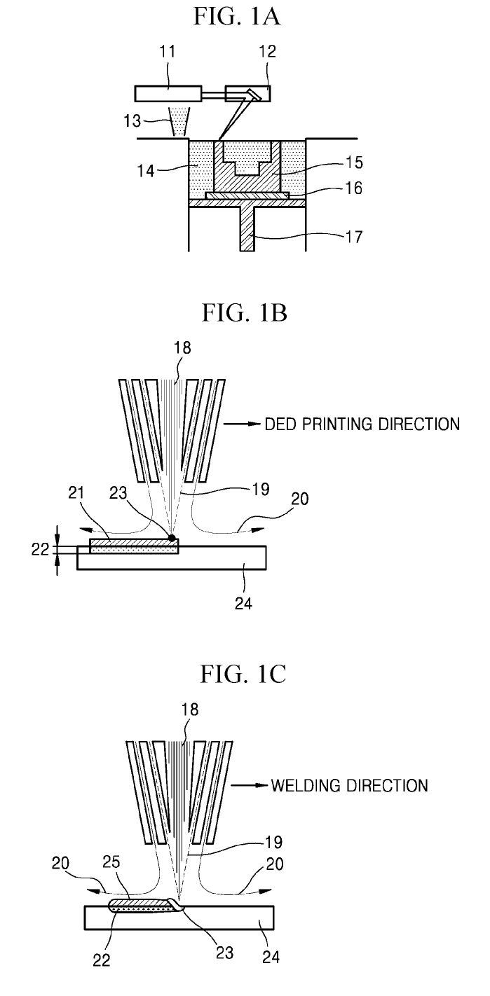

FIG. 1 is a diagram illustrating a PBF 3D printing, is a diagram illustrating a DED laser beam 3D printing, and is a conceptual diagram illustrating high energy laser beam metal powder welding that is the same as the DED laser beam 3D printing in terms of technology.

It can be seen that DED laser beam 3D printing is technically identical to high energy laser beam metal powder welding.

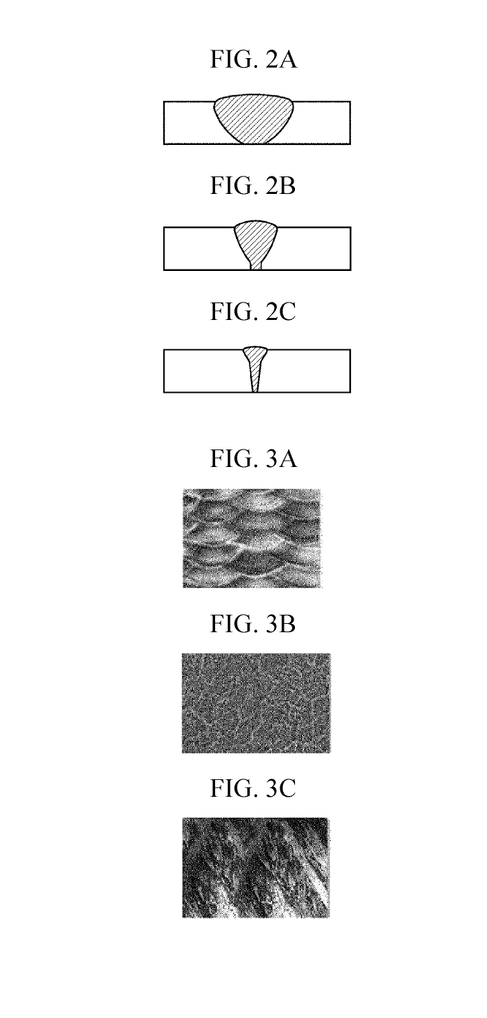

FIG. 2 is a cross-sectional view illustrating a shape of a printing part according to various input energy density.

More specifically, FIG. 2A is a cross-sectional view illustrating a shape of a printing part by low input energy density, FIG. 2B is a cross-sectional view illustrating a shape of the printing part by medium input energy density, FIG. 2C is a cross-sectional view illustrating a shape of the printing part by high input energy density which is technically the same as the DED laser beam 3D printing.

Since the DED laser beam 3D printing is technically identical to the high energy laser beam welding, it can be seen that an energy density per unit area of a printed part is large, and a penetration depth of a printed part is deep. Referring to FIG. 2C, it can be seen that a shape of the printed part of the DED laser beam 3D printing has a shape identical to a key hole due to a high energy beam.

Further, comparing the shapes of the printed parts shown in FIG. 2, it can be seen that FIG. 2A shows a lowest energy density, a most shallow penetration depth, and a most slow welding speed among FIGS. 2D, 2E, and 2F.

FIG. 3A-3C are diagram illustrating a macrostructure and a microstructure of a printing part of Japanese-made mold alloy steel on which the DED laser beam 3D alloy metal powder printing was performed.

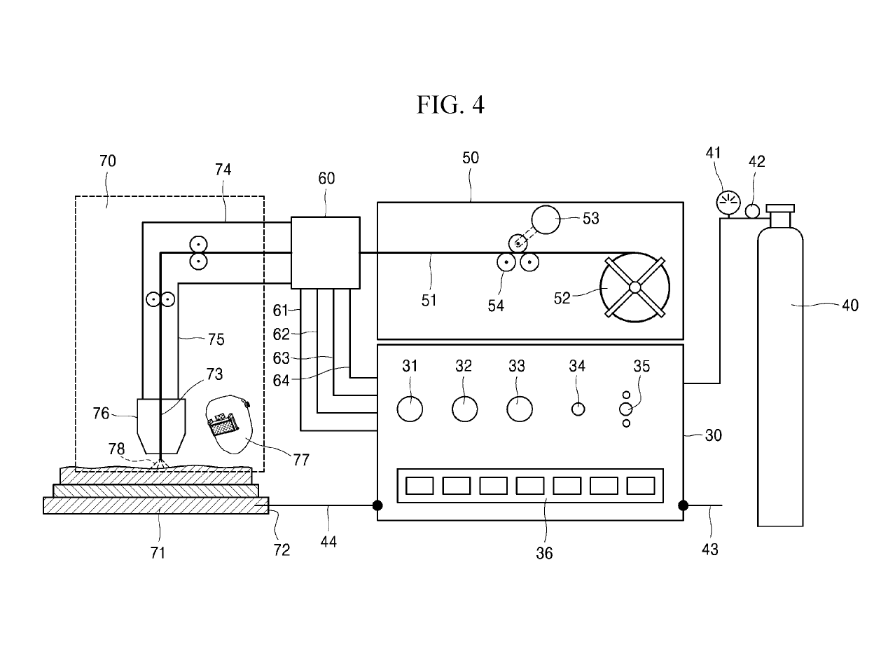

Referring to FIG. 3A, a heat-affected zone existing at a multilayer printing part and each of the printing parts can be seen from the macrostructure as in conventional multilayer welding. Since a laser beam is held at a single position in a short period of time and is widely moved, it can be seen that a printing penetration depth of a DED laser beam powder 3D printing part becomes deeper. Therefore, it can be seen that the DED laser beam 3D alloy metal powder printing method cannot obtain a flat part with a high heat density and a high temperature as in general overlay welding. Referring to FIGS. 3H and 31, it can be seen that the micro-structure has a combination of bainite and martensite, and this is because of hardening of micro-structure due to a fast cooling rate by high temperature gradient of high temperature and high energy intensity. FIG. 4 is a block diagram of a DED arc 3D alloy metal powder printing apparatus of the present invention.

Referring to FIG. 4, the DED arc 3D alloy metal powder printing apparatus according to an embodiment of the present invention includes a direct current (DC) constant voltage characteristic power supply device 30, a wire feeder 50, a printing gun device 70, a 3D printing part 71, and an inert gas container 40.

DC Constant Voltage Characteristic Power Supply Device (30)

The DC constant voltage characteristic power supply 30 includes a printing program 36, a voltage regulator 31, a current regulator 32, a wire feeding speed regulator 33, and a protective gas regulator 34.

After printing information is input to the DC constant voltage characteristic power supply device, a position and a speed of a 3D printing gun may be automatically controlled by a printing program according to the information. The information may include a magnitude of a current, a wire feeding speed, and a protective gas transfer speed, and the like.

More specifically, a software program, a motion-control positioning program, and other programs may be loaded into the printing program 36 to drive various actuators according to the input data and a path which are calculated from a 3D computer-aided design (CAD) model or other program models, thereby automatically and continuously performing 3D printing.

Wire Feeder 50

The wire feeder 50 includes a wire drive motor 53, an alloy metal powder cored wire 51 wound on a wire reel 52, and a wire feeder rotating roller 54 configured to supply the alloy metal powder cored wire 51.

The alloy metal powder cored wire 51 is wound on the wire reel 52 and is fed to a 3D printing gun 76 at a programmed speed through a drive motor and a rotating roller for wire feeding. When the alloy metal powder cored wire is fed through the wire feeder rotating roller, a feeding speed of the cored wire is varied according to a programmed rotating speed of the rotating roller of the wire feeder, and an arc length is kept constant even when a printing speed is varied, such that the feeding speed of the cored wire may be automatically controlled.

In the DED arc 3D alloy metal powder printing apparatus of the present invention, an arc is generated due to a potential difference between a first electrode and a second electrode. More specifically, a 3D printing part is connected to the first electrode through a ground line, and the alloy metal powder cored wire is configured as a filler metal, that is, the second electrode. The filler metal may be in the form of a wire instead of a powder to serve as the second electrode, and the alloy metal powder cored wire may be formed by filling a fine metal powder, that is, an alloy metal powder 19 into a thin tube-shaped wire instead of a solid wire.

The alloy metal powder cored wire includes an envelope 51a and the alloy metal powder 19. The alloy metal powder core wire has a dual purpose not only used as the second electrode for generating an arc but also used as the filler metal.

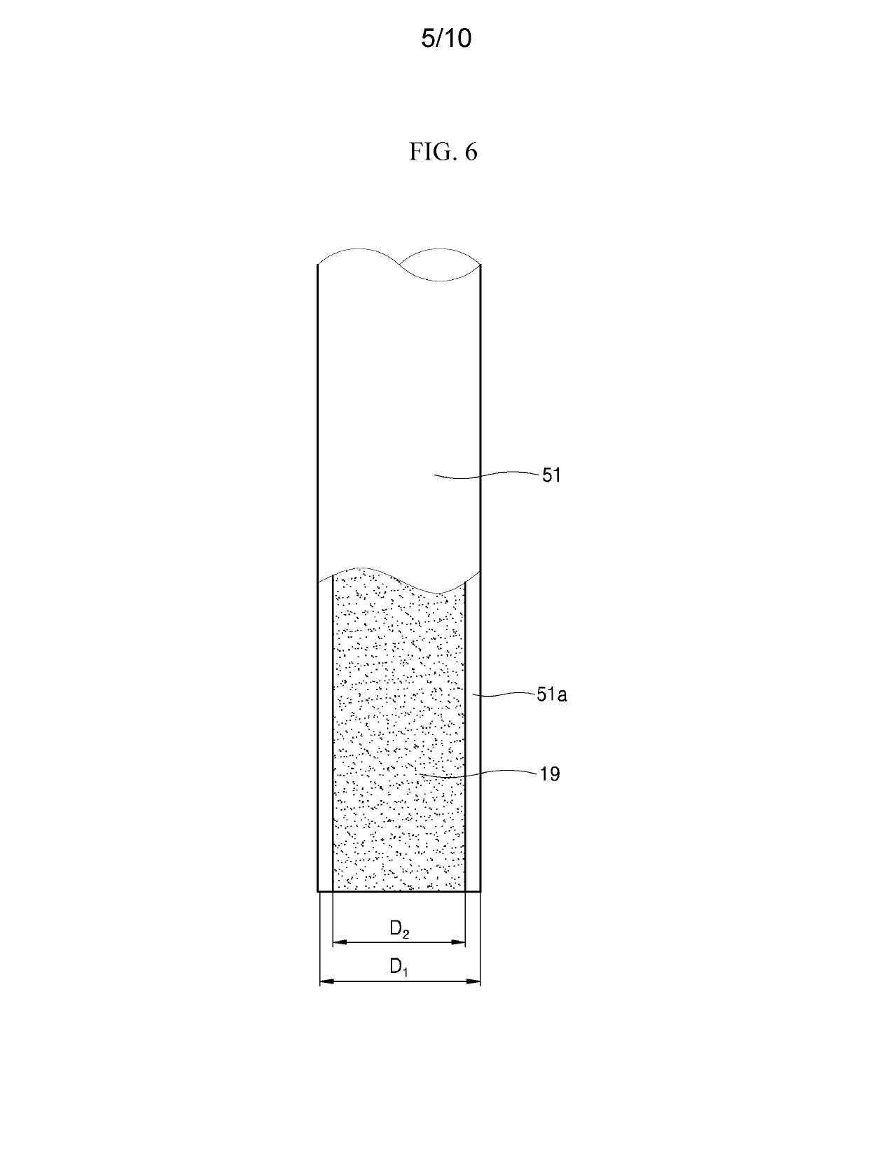

Referring to FIG. 6, an inner diameter D2 and an outer diameter D1 of the alloy metal powder cored wire and a diameter of the alloy metal powder may be varied according to printing accuracy, and at this point, a gap between the wire feeder rotating rollers and an inner diameter of the 3D printing gun may be adjusted according to the outer diameter D1 of the alloy metal powder cored wire.

Further, the envelope of the alloy metal powder cored wire and components of the alloy metal powder may be varied according to components of a metallic material which will be printed. The alloy metal powder cored wire may use all commercially available alloy metals such as carbon steel, stainless steel, a nickel alloy, an aluminum alloy, and the like as the tube and the alloy metal powder.

Chemical compositions of the tube and the alloy metal powder may be the same as each other or may be different from each other and be alloyed according to a physical property of the printing part which will be printed and obtained. In order to stabilize formation of the arc, a small amount of sodium (Na) and potassium (K) may be mixed into the alloy metal powder cored wire.

When a base material is provided before printing according to applicability, the chemical compositions of the alloy metal powder cored wire may be adjusted to equal chemical, physical, and mechanical properties thereof to those of the base material according to the chemical, physical, and mechanical properties of the base material, and thus chemical, physical, and mechanical properties of the printing part may be equal to those of the base material. This may be a case when repair or maintenance printing is performed on the base material through printing.

However, different dissimilar metal printing is also possible by differentiating the chemical compositions of the base metal from those of the alloy metal powder cored wire. For example, stainless steel for corrosion protection may be overlaid on a carbon steel printing part, or a suitable alloy may be overlaid on the carbon steel printing part.

Current flows along the tubed envelope 51a, and since the envelope 51a is thin, a current density is high and thus a melting rate of the tubed envelop is high. Therefore, when the same current flows, an alloy metal powder core type, that is, a tube type wire, has melting efficiency higher than the solid wire, and thus the alloy metal powder core type may have a high printing rate and stacking efficiency as that of the alloy metal powder used in a laser beam DED technique. That is, the thickness of the envelope 51a becomes thinner as the inner diameter D2 of the alloy metal powder core wire becomes larger and the outer diameter D1 becomes smaller, so that the melting rate becomes faster such that high speed and accurate printing can be performed. The outer diameter of the cored wire may be in the range from 1/32 inches to ⅛ inches, but the outer diameter may be adjusted in consideration of a special purpose.

Accordingly, the printing speed and the melting rate may be varied by controlling thicknesses of the inner and outer diameters of the tube wire.

Printing Gun Device 70 and 3D Printing Part 71

The printing gun device 70 includes the alloy metal powder cored wire 51, an inert gas tube 74, and a 3D printing gun 76 enclosing an inert gas tube 74 disposed at on both sides of the cored wire.

The 3D printing part 71 is disposed below the printing gun device 70 and is in partial contact with a front end of the cored wire.

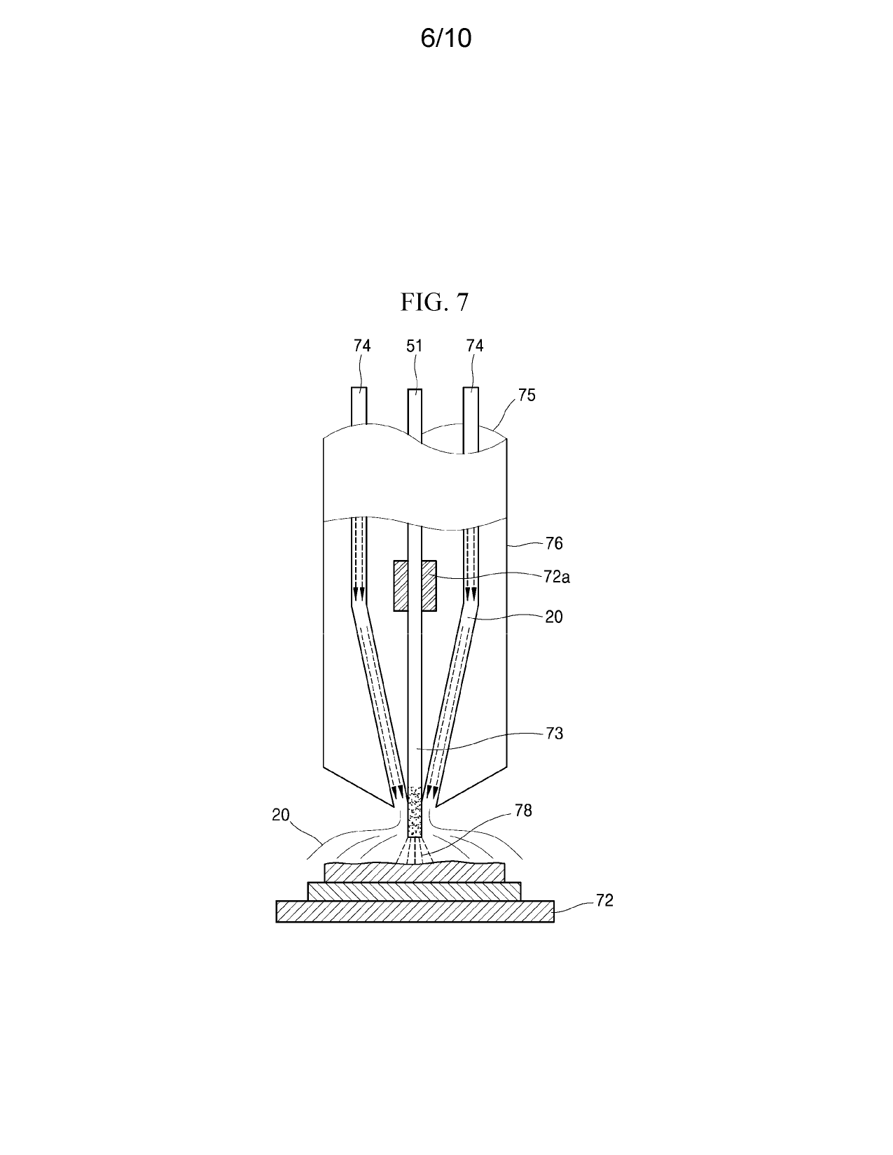

Referring to FIGS. 4 and 7, in order to generate an arc that is a heat source for 3D printing, the base material that is a 3D printing part is connected to the first electrode which is set to a negative (−) electrode. An electrode contact tip 72a set as a positive polarity (+) may be tapped on the alloy metal powder cored wire to form the second electrode. A surface of the printing part of the 3D printing part which is the first electrode is instantaneously brought into contact with the second electrode at an instant, and then a constant gap is kept such that an arc is generated by a potential difference between the first and second electrodes.

Inert Gas Container 40

The inert gas container 40 is connected to the DC constant voltage characteristic power supply device.

Referring to FIGS. 4 and 7, the 3D printing of the present invention may be shielded from the outside using a protective gas so as to improve quality of the printing part. An inert gas such as argon (Ar) or helium (He) having a purity of 99.99% may be selectively used as the protective gas.

When an argon gas is used at the same magnitude of a current, heat is relatively more dissipated than a case in which the argon gas is not used, such that the melting rate can be increased. Further, a larger amount of melt at the wire can be transferred downward due to a high melting rate, and a melt transfer is a spray-type such that a high printing rate can be obtained.

An integrated 3D printing apparatus may accommodate all components such as 5 to 6 axis motion CNC router, the DC constant voltage characteristic power supply device, the wire feeding device, and the inert gas container, the 3D printing gun, related cables, gas supply pipes, and the like in the printing gun device 70. The printing gun apparatus may be provided with a glass wall for shielding ultra-violet around the arc and 3D printing gun so as to observe movements of the arc and the 3D printing gun. When the glass wall is opened to directly observe, a personal face protection helmet is required, and the helmet may be stored by installing a storage enclosure in the printing gun device.

A separable type may be used by separating only the 3D printing gun, the related cables, and the gas supply pipes among the integrated components according to a usage condition. In the separable type, a printing speed of the 3D printing gun may be varied according to a software program command, be freely moved forward, backward, left, and right, or be manually printed without the software program command. The separable type may be used to move only a printing gun connected with a long current cable at a place where the integrated printing device is difficult to access, and at this point, separated parts may be fixed to a place where printing is performed for a 3D printing part and thus the printing gun may be freely moved to perform the printing along a programmed path or may be used as a hand-held type.

In the case of a separable 3D printing device, a personal face protection helmet is needed.

Since the printing apparatus of the present invention has a heat source of an arc, maintenance and installation are easier than a laser beam printing apparatus and a heat input of the printing part is controllable such that printing part having desired micro-structures and desired mechanical properties are manufactured.

Further, the DED arc 3D alloy metal powder printing apparatus of the present invention does not need to consider a fume treatment because of using the arc as the heat source, but as necessary, the DED arc 3D alloy metal powder printing apparatus may further include a fume transfer passage.

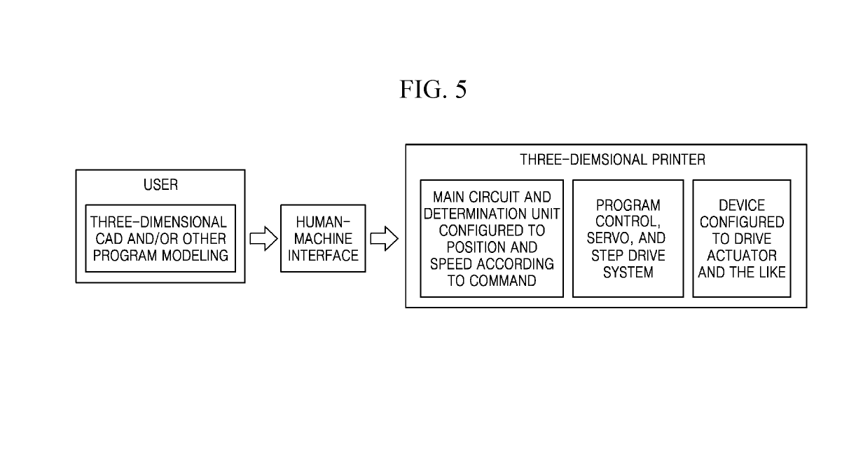

FIG. 5 is a flowchart of a DED arc 3D alloy metal powder printing method of the present invention.

Referring to FIG. 5, a user inputs information to a DC constant voltage power supply device for a 3D CAD program produced with a 2D drawing and printing. The 3D printing apparatus may control a program through a man-machine interface, drive various actuators, and automatically perform 3D printing according to the inputted information as a robot. The information, which will be input by the program, may include magnitudes of a current and a voltage, a wire feeding speed, and a protective gas movement speed and may further include a CAD program, path information of the printing gun, constant voltage characteristic information, and the like.

According to the inputted information, process parameters affecting to accuracy in height of the metal monolayer corresponding to the 2D cross section in the 3D printing may be controlled in real time, so that the metal monolayer with a very accurate thickness may be manufactured, and a metal product identical to a 3D CAD model may be manufactured by repeatedly stacking the metal monolayers.

More specifically, a DED arc 3D alloy metal powder printing method according to an embodiment of the present invention includes the steps of: (a) connecting a 3D printing object to a first electrode through a ground line, bringing a second electrode on which an electrode contact tip is tapped on a circumferential surface of an alloy metal powder cored wire into contact with a portion of a surface of the printing part of the object, and generating an arc by a potential difference between the first electrode and the second electrode to simultaneously melting a tip of the alloy metal powder cored wire and the surface of the printing part, (b) forming a monolayer by mixing and solidifying melts of the alloy metal powder cored wire and the surface of the printing part, and (c) continuously performing a monolayer overlay to stack the monolayers.

As described above, the steps (a) to (c) are performed in an inert gas atmosphere having a purity of 99.99%.

Further, after information is input to the DC constant voltage characteristic power supply device including the printing program, the voltage regulator, the current regulator, the wire feeding speed regulator, and the protective gas regulator, an arc length and a wire feeding speed may be automatically controlled by the printing program 36 according to the input information.

As described above, the information may further include a protective gas movement speed and the like in addition to the magnitude of the current and the wire feeding speed.

For example, when a current having a magnitude in the range of approximately 35 to 90 A is input through the current regulator of the DC constant voltage characteristic power supply device, the printing program operates according to the magnitude of the current. At this point, the printing program 36 may automatically determine an arc voltage in the range of 13 to 17 V according to a DC constant voltage characteristic. Further, the wire feeding speed may be automatically determined in the range of 2 to 8 m/min, and a protective gas flow rate may be automatically determined in the range of 5 to 10 L/min. At this point, an arc length may be adjusted in the range of approximately 2 to 10 mm.

When the wire feeding speed and the protective gas flow rate are decreased or increased, the wire feeding speed and the protective gas flow rate may be manually adjusted through the wire feeding speed regulator, the protective gas regulator, and the like.

Further, the alloy metal powder cored wire may be formed as described above.

In this case, a DC reverse polarity may be applied such that negative electrons (−) are moved from the surface of the printing part to the alloy metal powder cored wire, and gas ions (+) collide with the surface of the printing part to remove a harmful thin film on the surface thereof.

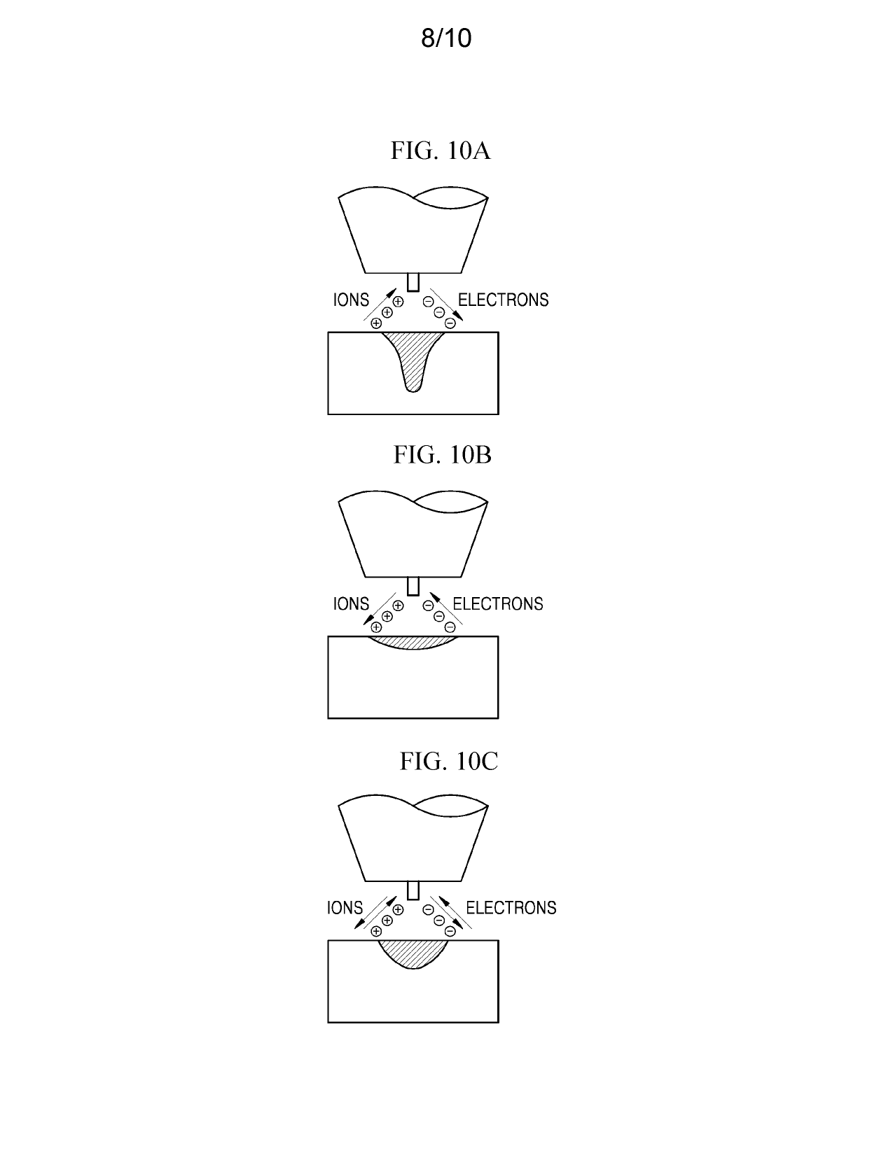

Referring to FIG. 10B, the DC reverse polarity may set the cored wire as a positive (+) pole and the printing part as a negative (−) pole. As the negative electrons are moved from a base material or the printing part to an alloy metal powder cored wire electrode, the melting rate of the continuously supplied alloy metal powder cored wire is increased, and printing may be performed at a high speed. Since the 3D printing is to overlay and stack thin monolayers, a most preferable 3D printing part having a shallow welded penetration and a wide width may be manufactured. Further, since the DC reverse polarity serves as a cleaning action removing oxide or nitride films, and the like on the surface of the printing part with a collision of a (+) ion gas with the surface thereof, there is an effect of preventing a discontinuities of the printing part.

FIG. 10A is a cross-sectional view illustrating flows of electrons and ions, a penetration depth, and a shape in the case of the DC positive polarity. The DC positive polarity may set the cored wire as a (−) pole and the printing part as a (+) pole. The electrons are moved from the cored wire to the base material. The DC positive polarity has a characteristic in that, since the electrons having a high speed collide with the base material from the electrode, so that the penetration depth becomes deeper and a width of the printing part becomes narrower.

FIG. 10C is a cross-sectional view illustrating flows of electrons and ions, a penetration depth, and a shape in the case of an alternating current. Printing may be performed while electrons and ions are moved between the cored wire and the base material, and a welded penetration may can be shallower than that in the case of the DC positive polarity.

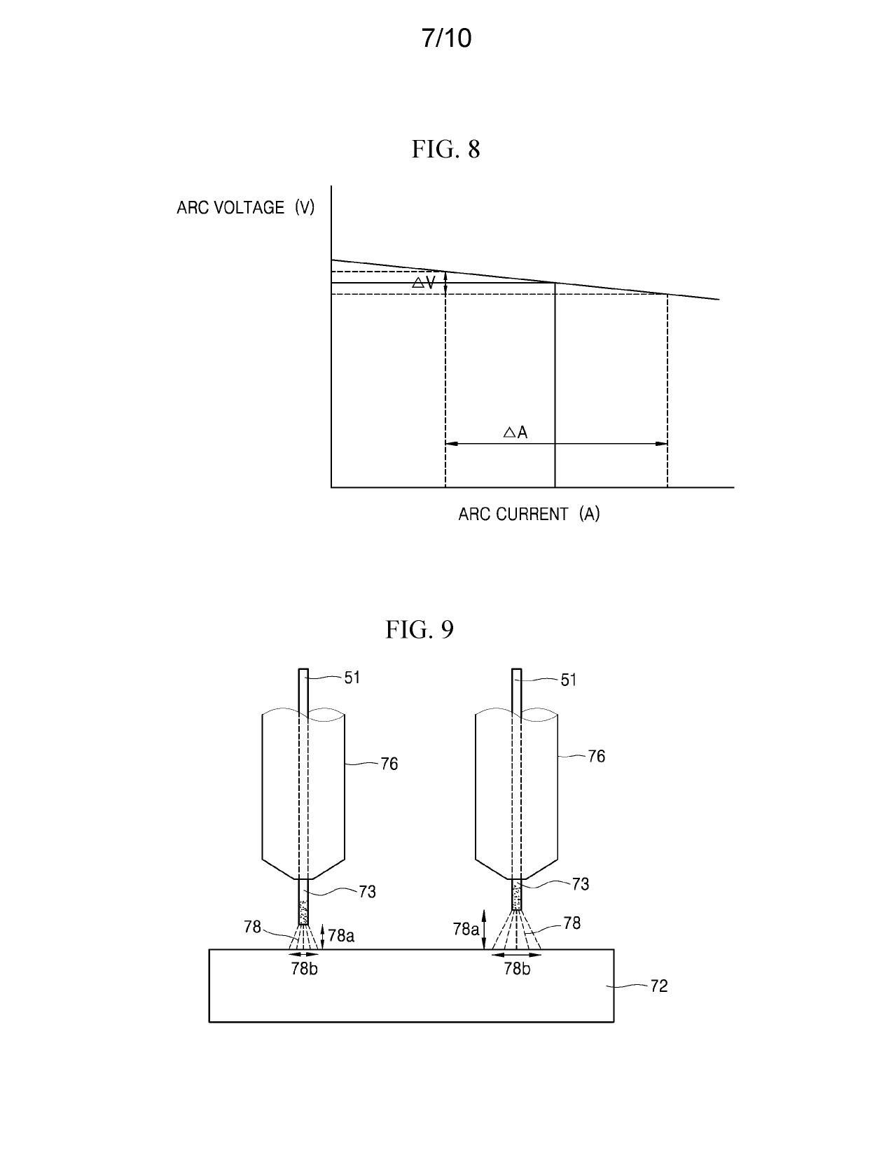

Referring to FIG. 9, a gap between the tip of the alloy metal powder cored wire and the surface of the printing part represents the arc length. In FIG. 9, when an arc length 78a becomes longer, the arc voltage becomes higher, the printing part may become thinner, an arc width 78b may become widener, and a flat printing part may be manufactured. On the other hand, in FIG. 9, the arc length 78a becomes shorter and thus the arc width 78b may become narrower.

Since the arc length and heating generated by the arc are directly proportional to each other, a shape of the printing part can be controlled by controlling the wire feeding speed to adjust the arc length 78a and the arc width 78b.

More specifically, the arc length is preferably in the range of 2 to 10 mm.

When the arc length is less than 2 mm, the printing part may be formed in a key hole shape, and contrarily, when the arc length exceeds 10 mm, a melting process by the arc may not be appropriately performed and quality of the printing part may be degraded due to generation of spatter.

Further, in consideration of the arc length, the arc voltage and the movement speed of the 3D printing gun may be controlled. The heat input of 3D printing determine the shape of a molten pool of the printing part, and a cooling rate is determined according to the heat input such that micro-structure and mechanical properties of the printing part are determined.

The heat input (Q) of the printing unit is preferably in the range of 114 J/cm≤heat input≤136 J/cm.

When the heat input is less than 114 J/cm, the penetration depth becomes shallower and the micro-structure and mechanical properties of the printing part may be uneven. On the other hand, when the heat input exceeds 136 J/cm, the shape of the printing part may be formed in a key hole shape, and quality of the micro-structures and resulted mechanical properties of the printing part may be degraded.

The 3D printing gun may be rectilinearly moved over a printing line along a programmed path or may be weaved and moved in a zigzag pattern based on the printing line so as to obtain a wide-width printing part. Since a temperature of a central portion of the printing part is higher than those at both ends of a width of the printing part, a printing speed may be controlled to be slow at both ends, and in order to prevent deformation of the printing part due to shrinkage during solidification, the printing is performed while overlapping both ends, such that printing speed control and the quality of the printing part can be improved.

Referring to FIG. 8, it can be seen that a terminal voltage is a constant voltage characteristic curve which is not significantly varied even when a load current is varied. The DED arc 3D alloy metal powder printing of the present invention includes the DC power supply device, so that it is safe to use and the component structures are simple. Further, since device operation is noiseless and a current flows in one direction, the arc is stably formed and a constant voltage is kept constant even when a load is varied, so that there is an advantage in that a monolayer having a uniform thickness may be continuously stacked at a high speed.

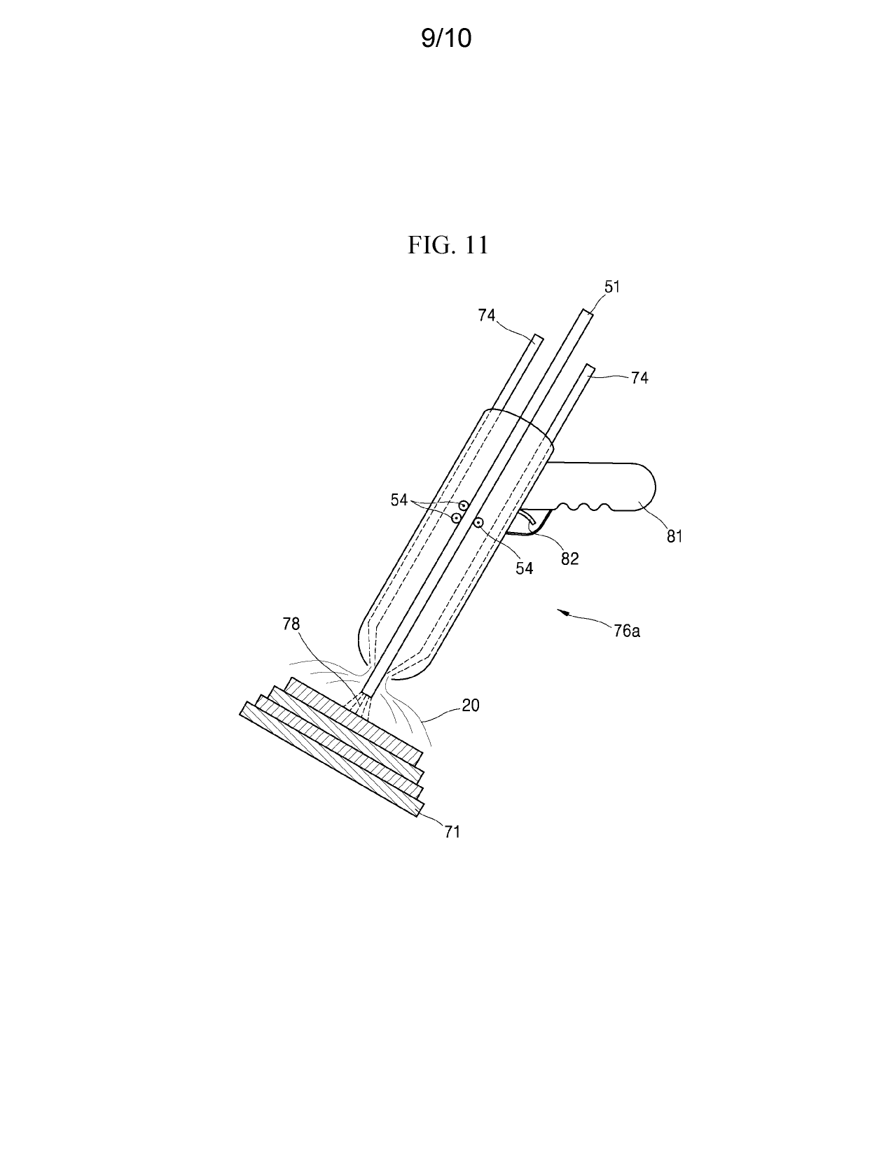

FIG. 11 is a diagram illustrating a mobile hand-held 3D printing gun 76a which allows an operator to manually hold a printing gun instead of a fixed 3D printing gun. The operator may freely perform printing by manually moving the 3D printing gun. In this case, although the arc length may be varied during printing due to a manual operation, a voltage is not varied due to a constant voltage characteristic even when the arc length is varied, a certain amount of heating can be obtained and thus high quality of the printing part can be obtained. In this case, for the 3D printing, the operator may wear the personal face protective helmet 77 to perform printing.

The mobile hand-held 3D printing gun supplies the alloy metal powder cored wire as in the DED arc 3D alloy metal powder printing of the present invention, so that printing of all positions such as a flat, an overhead, a horizontal, a vertical, and the like can be performed regardless of an apparatus types such as integrated, separable, fixed, and hand-held.

As described above, since the mobile hand-held 3D printing gun can be manually operated, the workability may be improved.

Accordingly, the 3D printing may be performed either using printing gun fixed to or separated from the apparatus, which is capable of allowing the operator to perform printing manually or automatically.

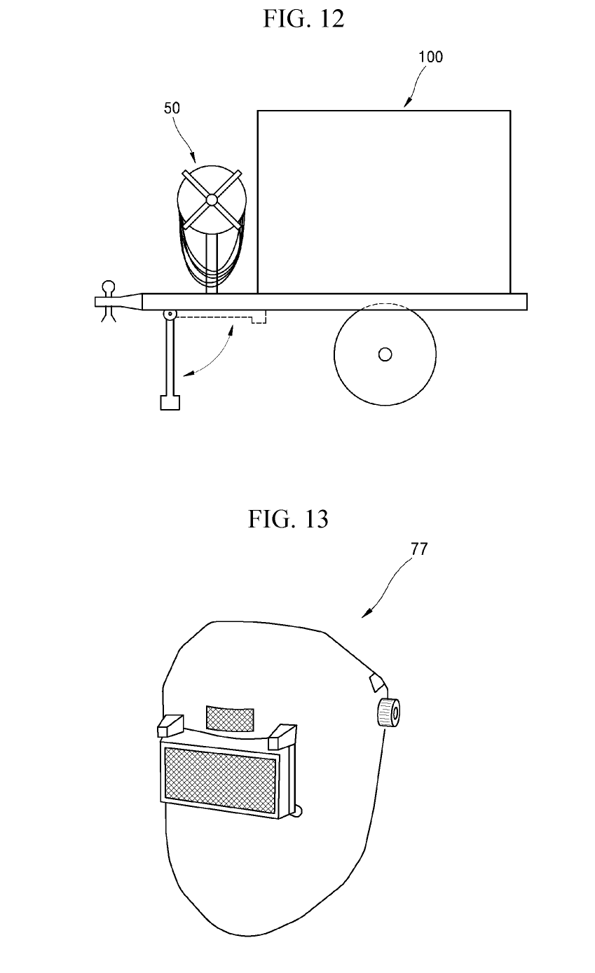

FIG. 12 is a cross-sectional view illustrating a state in which a main body of a 3D printing apparatus of the present invention loaded on a trailer and a cable and a hose separated from the main body are wound on a reel.

Referring to FIG. 12, when transportation is required, the 3D printing gun, the cable, the hose, and the like together with the wire feeder 50 may be loaded in a storage space 100 and moved to a desired location.

As described above, the DED arc 3D alloy metal powder printing apparatus of the present invention can be operated reliably, efficiently, and at a high speed regardless of printing ability of the operator due to full automation and flexibility of selection. The arc may be stably formed and superior 3D printing is possible, and specifically, miniaturization and a mobile type are possible, so that it can be applied to anywhere in the filed or a shop, and a reasonable price entry type can be realized.

While the embodiments of the present invention have been described with reference to the accompanying drawings, the present invention is not limited to these embodiments and can be modified different various forms, and those skilled in the art to which the present invention pertains can understand the other specific forms can be implemented without departing from the technical spirit and essential features of the present invention. Therefore, it should be understood that the above-described embodiments are not restrictive but illustrative in all aspects.

1. A directed energy deposition (DED) arc 3D printing method using an arc and an alloy metal powder cored wire, the method comprising the steps of:
(a) connecting a 3D printing part to a first electrode through a ground line, bringing a second electrode on which an electrode contact tip is tapped on a circumferential surface of an alloy metal powder cored wire into contact with a portion of a surface of the printing part, and generating an arc by a potential difference between the first electrode and the second electrode to simultaneously melting a tip of the alloy metal powder cored wire and the surface of the printing part;
(b) forming a monolayer by mixing and solidifying melts of the alloy metal powder cored wire and the surface of the printing part; and
(c) continuously performing a monolayer overlay to stack the monolayers, layer-upon-layer and
wherein the steps (a) to (c) are performed in an inert gas atmosphere,
after information including a printing program, a voltage regulation, a current regulation, a wire feeding speed regulation, and a protective gas regulation is input to a direct-current (DC) constant voltage characteristic power supply device, an arc length and a wire feeding speed is automatically controlled by the printing program according to the input information,
the alloy metal powder cored wire is formed by filling an alloy metal powder in a tube-shaped wire, and a heat input Q of the printing part follows the following equation:
114 J/cm≤heat input≤136 J/cm,
wherein heat input=arc voltage (V)×arc current (A)÷printing speed of 3D printing gun (cm/sec).

2. The printing method of claim 1, wherein a DC reverse polarity is chosen such that negative electrons (−) are moved from the surface of the printing part to the alloy metal powder cored wire, and gas ions (+) collide with the surface of the printing part to remove oxide or impurity thin film on the surface thereof.

3. The printing method of claim 1, wherein an arc length is in a range of 2 to 10 mm.

4. A directed energy deposition (DED) 3D printing apparatus using an arc and an alloy metal powder cored wire, the apparatus comprising:
a direct-current (DC) constant voltage characteristic power supply device including a printing program, a voltage regulator, a current regulator, a wire feeding speed regulator, and a protective gas regulator;
a wire feeding device including a wire drive motor, an alloy metal powder cored wire wound on a wire reel, and a wire feeder rotating roller configured to supply the alloy metal powder cored wire;
a printing gun device including the alloy metal powder cored wire, an inert gas pipe, and a 3D printing gun enclosing the inert gas pipe located on both sides of the cored wire;
a 3D printing part sculpture disposed below the printing gun device and brought in partial contact with a front end of the cored wire; and
an inert gas container connected to the DC constant voltage characteristic power supply device,
wherein, after information is input to the DC constant voltage characteristic power supply device, a position and a speed of a 3D printing gun is automatically controlled by a printing program according to the input information, the information includes a magnitude of a current and a wire feeding speed, the alloy metal powder cored wire is formed by filling an alloy metal powder in a tube-shaped wire.

5. The printing apparatus of claim 4, the 3D printing may be performed either using printing gun fixed to or separated from the apparatus, which can allow the operator to perform printing manually or automatically.

6. The printing apparatus of claim 4, wherein an arc length is in a range of 2 to 10 mm.
